(19) United States
(12) Patent Application Publication
(10) Pub. No.: US 2007/0195499 A1
(43) Pub. Date: Aug. 23, 2007

(54) Computer housing assembly with a cooling device

(76) Inventor: Ping-Chun Chu, Taipei Hsien (TW)

Correspondence Address: SEYFARTH SHAW LLP, 131 S. DEARBORN ST., SUITE2400, CHICAGO, IL, 60603-5803, US

(21) Appl. No.: 11/707,438

(22) Filed: Feb. 16, 2007

(30) Foreign Application Priority Data
Feb. 21, 2006 (TW) 095202904

(51) Int. Cl. H05K 7/20

(52) U.S. Cl. 361/695

(57) ABSTRACT

A computer housing assembly includes a computer housing, a cooling device, and a temperature control device. The cooling device is mounted on the computer housing, and includes a thermoelectric chip, a cooling fan, and a cover. The thermoelectric chip has a cold side disposed in the computer housing and provided with a finned structure. The cover is formed with outlet and inlet openings, and encases the thermoelectric chip, the finned structure, and the cooling fan. The cooling fan draws air from the computer housing through the inlet opening, and expels the air through the outlet opening back to the computer housing. The temperature control device controls operation of the thermoelectric chip to maintain temperature of the air in the computer housing above the dew point temperature.

### CROSS-REFERENCE TO RELATED APPLICATION

This application claims priority of Taiwanese application no. 095202904, filed on Feb. 21, 2006.

### BACKGROUND OF THE INVENTION

1. Field of the Invention

The invention relates to a computer housing assembly, more particularly to a computer housing assembly that incorporates a cooling device.

2. Description of the Related Art

A conventional heat-dissipating device, as illustrated in FIG. 1, includes a finned structure 92 that is disposed on and that absorbs heat from a central processing unit (not shown) in a computer housing 91, and a cooling fan 93 that transfers the heat absorbed by the finned structure 92 into the air circulating in the computer housing 91.

The aforementioned conventional heat-dissipating device is disadvantageous in that it merely accumulates the heat in the computer housing 91. This eventually leads to a rise in the temperature of the air in the computer housing 91.

It has been proposed to solve the above problem using a thermoelectric chip (not shown) to cool the air in the computer housing 91. However, this causes another problem. That is, moisture, due to condensation, tends to form on the thermoelectric chip, which may cause shorting-circuiting of electronic components in the computer housing 91.

### SUMMARY OF THE INVENTION

Therefore, the object of the present invention is to provide a computer housing assembly that can overcome the aforesaid drawback of the prior art.

According to the present invention, a computer housing assembly comprises a computer housing, a cooling device, and a temperature control device. The computer housing defines an interior space. The cooling device is mounted on the computer housing, and includes a thermoelectric chip, first and second finned structures, a cooling fan, and a cover. The thermoelectric chip has a cold side disposed in the interior space in the computer housing, and a hot side opposite to the cold side. The first finned structure is provided on the cold side of the thermoelectric chip. The second finned structure is provided on the hot side of the thermoelectric chip and is disposed externally of the computer housing. The cooling fan is disposed in the interior space in the computer housing proximate to the first finned structure. The cover is disposed in the interior space in the computer housing, is formed with outlet and inlet openings, and encases the cold side of the thermoelectric chip, the first finned structure, and the cooling fan. The cooling fan is operable so as to draw air from the interior space in the computer housing into the cover through the inlet opening and so as to expel the air out of the cover through the outlet opening back to the interior space in the computer housing. The temperature control device is coupled to the thermoelectric chip, and is operable so as to control operation of the thermoelectric chip in order to maintain temperature of the air in the interior space in the computer housing above the dew point temperature.

### BRIEF DESCRIPTION OF THE DRAWINGS

Other features and advantages of the present invention will become apparent in the following detailed description of the preferred embodiments with reference to the accompanying drawings, of which:

FIG. 1 is a perspective view of a conventional heat-dissipating device in a state of use;

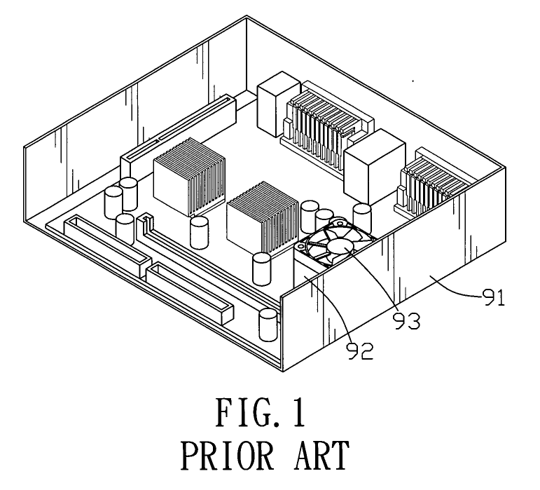

FIG. 2 is an exploded perspective view of the first preferred embodiment of a computer housing assembly according to the present invention;

FIG. 3 is a perspective view to illustrate a cooling device of the first preferred embodiment;

FIG. 4 is a fragmentary sectional view to illustrate operation of the cooling device of the first preferred embodiment; and

FIG. 5 is a fragmentary sectional of the second preferred embodiment of a computer housing assembly according to the present invention.

### DETAILED DESCRIPTION OF THE PREFERRED EMBODIMENTS

Before the present invention is described in greater detail, it should be noted that like elements are denoted by the same reference numerals throughout the disclosure.

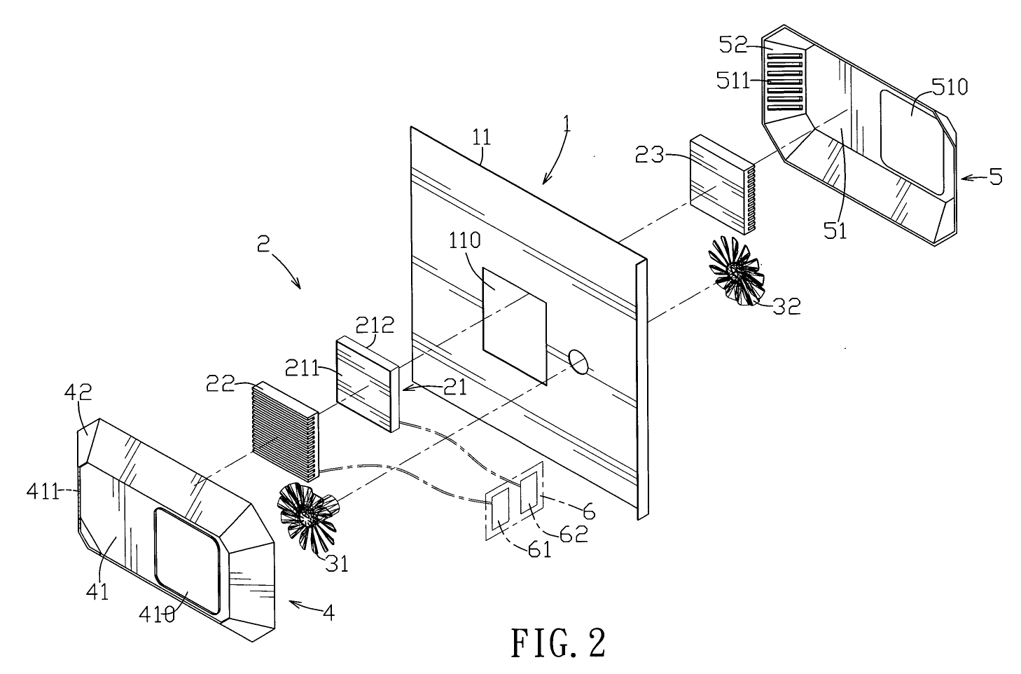

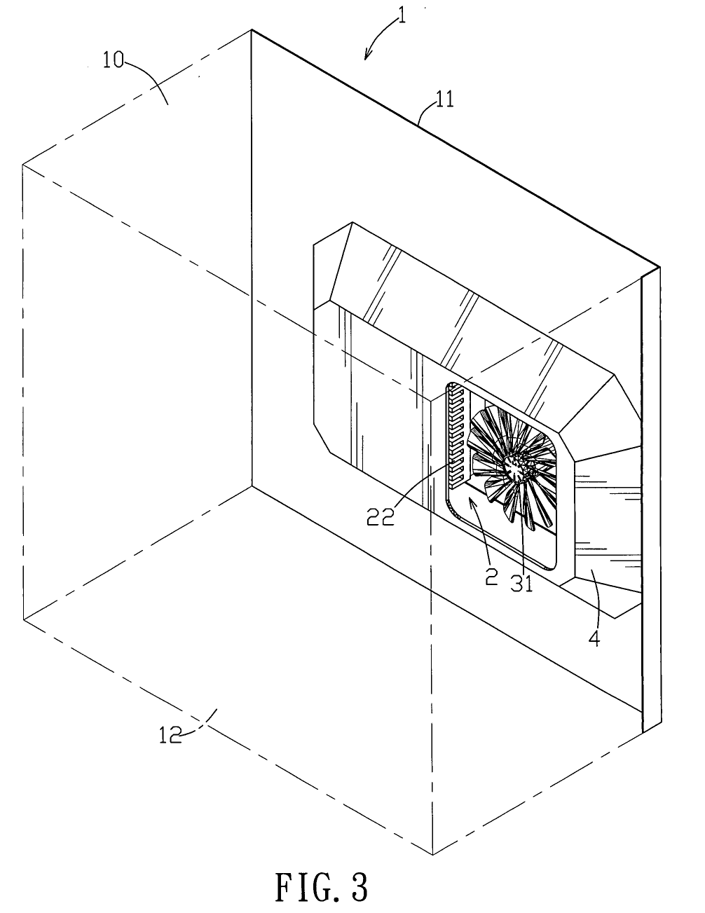

Referring to FIGS. 2 and 3, the first preferred embodiment of a computer housing assembly according to this invention is shown to include a computer housing 1, a cooling device 2, and a temperature control device 6.

The computer housing 1 includes opposite first and second lateral walls 11, 12 that cooperatively define an interior space 10 therebetween. In this embodiment, the first lateral wall 11 of the computer housing 1 is formed with a through-hole 110 that is in spatial communication with the interior space 10 in the computer housing 1.

The cooling device 2 is mounted on the first lateral wall 11 of the computer housing 1, and includes a thermoelectric chip 21, first and second finned structures 22, 23, first and second cooling fans 31, 32, and first and second covers 4, 5.

The thermoelectric chip 21 has opposite cold and hot sides 211, 212, is mounted in the through-hole 110 in the first lateral wall 11 of the computer housing 1 such that the cold side 211 thereof is disposed in the interior space 10 in the computer housing 1 and such that the hot side 212 thereof is disposed externally of the computer housing 1. Since the construction and operation of the thermoelectric chip 21 are known to those skilled in the art, a detailed description of the same will be dispensed with herein for the sake of brevity.

The first finned structure 22 is provided on the cold side 211 of the thermoelectric chip 21, and is therefore disposed in the interior space 10 in the computer housing 1.

The second finned structure 23 is provided on the hot side 212 of the thermoelectric chip 21, and is therefore disposed externally of the computer housing 1.

The first cooling fan 31 is disposed in the interior space 10 in the computer housing 1 proximate to the first finned structure 22.

The second cooling fan 32 is disposed externally of the computer housing 1 proximate to the second finned structure 23.

The first cover 4 is disposed in the interior space 10 in the computer housing 1, and encases the cold side 211 of the thermoelectric chip 21, the first finned structure 22, and the first cooling fan 31. In this embodiment, the first cover 4 includes a base wall 41 and a surrounding wall 42. The base wall 41 of the first cover 4 is disposed parallel to the first lateral wall 11 of the computer housing 1, and is formed with an outlet opening 410 disposed proximate to the first cooling fan 31. The surrounding wall 42 of the first cover 4 extends from the base wall 41 of the first cover 4, and is formed with a plurality of inlet openings 411 disposed proximate to the first finned structure 22.

The second cover 5 is disposed externally of the computer housing 1, and encases the hot side 212 of the thermoelectric chip 21, the second finned structure 23, and the second cooling fan 32. In this embodiment, the second cover 5 includes a base wall 51 and a surrounding wall 52. The base wall 51 of the second cover 5 is disposed parallel to the first lateral wall 11 of the computer housing 1, and is formed with an outlet opening 510 disposed proximate to the second cooling fan 32. The surrounding wall 52 of the second cover 5 extends from the base wall 51 of the second cover 5, and is formed with a plurality of inlet openings 511 disposed proximate to the second finned structure 23.

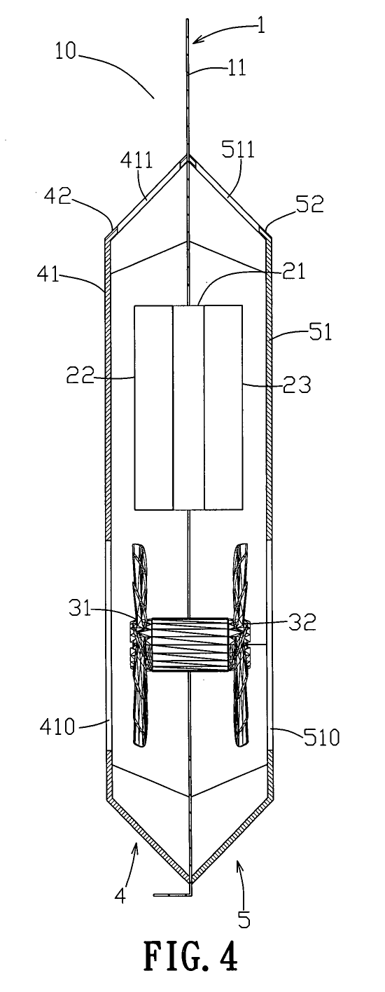

In operation, with further reference to FIG. 4, the first cooling fan 31 first draws air from the interior space 10 in the computer housing 1 into the first cover 4 through the inlet openings 411 in the surrounding wall 42 of the first cover 4, while at the same time, the second cooling fan 32 draws external air into the second cover 5 through the inlet openings 511 in the surrounding wall 52 of the second cover 5. The first finned structure 22 then absorbs heat from and therefore cools the air in the first cover 4. At this time, the heat absorbed by the first finned structure 22 is transferred to the second finned structure 23 through the thermoelectric chip 21, and is subsequently absorbed by the air in the second cover 5. The first cooling fan 31 then expels the cooled air in the first cover 4 out of the first cover 4 through the outlet opening 410 in the base wall 41 of the first cover 4 back to the interior space 10 in the computer housing 1, while at the same time, the second cooling fan 32 expels the warm air in the second cover 5 out of the second cover 5 through the outlet opening 510 in the base wall 51 of the second cover 5.

The temperature control device 6 is operable so as to control operation of the thermoelectric chip 21 in order to maintain temperature of the air in the interior space 10 in the computer housing 1 above the dew point temperature. In particular, the temperature control device 6 includes a sensor 61, a current source 62, and a control chip (not shown). The sensor 61 of the temperature control device 6 is in contact with and detects temperature of the first finned structure 22. The current source 62 of the temperature control device 6 is coupled electrically to the thermoelectric chip 21. The control chip of the temperature control device 6 is configured with lower and upper temperature thresholds that are above the dew point temperature, and is operable so as to permit and prevent operation of the thermoelectric chip 21 based on the lower and upper temperature thresholds configured therein and the temperature detected by the sensor 61.

From the above description, since the heat in the air in the interior space 10 in the computer housing 1 is transferred outside of the computer housing 1 via the thermoelectric chip 21, the temperature of the air in the interior space 10 of the computer housing 1 is kept cool. Moreover, since the cooling device 2 operates without drawing the external air into the interior space 10 in the computer housing 1, accumulation of dust in the interior space 10 in the computer housing 1 is prevented. Finally, since the temperature control device 6 maintains the temperature of the air in the interior space 10 in the computer housing 1 above the dew point temperature, formation of moisture, due to condensation, on the thermoelectric chip 21 is prevented.

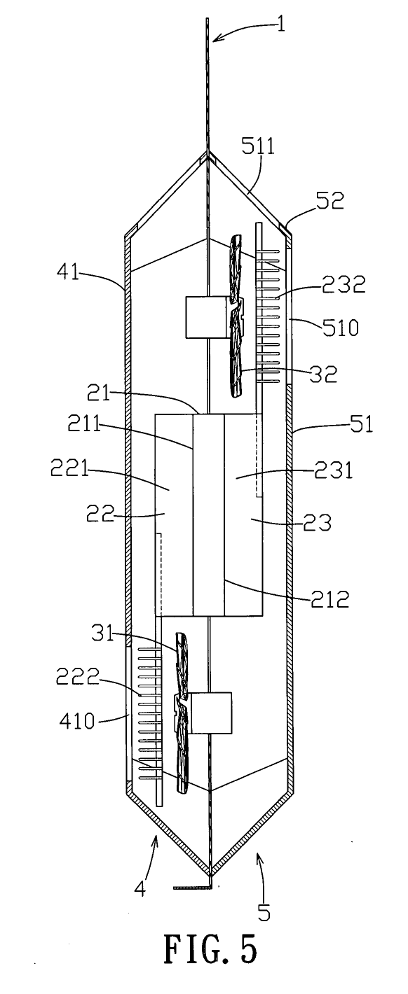

FIG. 5 illustrates the second preferred embodiment of a computer casing 1 according to this invention. When compared to the previous embodiment, the first finned structure 22 includes a heat sink body 221 that is attached to the cold side 211 of the thermoelectric chip 21, and an extension 222 that extends from the heat sink body 221 thereof, that is provided with a plurality of fins, and that is disposed between the first cooling fan 31 and the outlet opening 410 in the base wall 41 of the first cover 4.

The outlet opening 510 in the base wall 51 of second cover 5 and the inlet opening 511 in the surrounding wall 52 of the second cover 5 are disposed proximate to the second cooling fan 32.

The second finned structure 23 includes a heat sink body 231 that is attached to the hot side 212 of the thermoelectric chip 21, and an extension 232 that extends from the heat sink body 231 thereof, that is provided with a plurality of fins, and that is disposed between the second cooling fan 32 and the outlet opening 510 in the base wall 51 of the second cover 5.

While the present invention has been described in connection with what are considered the most practical and preferred embodiments, it is understood that this invention is not limited to the disclosed embodiments but is intended to cover various arrangements included within the spirit and scope of the broadest interpretation so as to encompass all such modifications and equivalent arrangements.

What is claimed is:

1. A computer housing assembly, comprising:
a computer housing defining an interior space;
a cooling device mounted on said computer housing, and including
a thermoelectric chip having a cold side disposed in said interior space in said computer housing, and a hot side opposite to said cold side,
a first finned structure provided on said cold side of said thermoelectric chip,
a second finned structure provided on said hot side of said thermoelectric chip and disposed externally of said computer housing,
a cooling fan disposed in said interior space in said computer housing proximate to said first finned structure, and
a cover disposed in said interior space in said computer housing, formed with outlet and inlet openings, and encasing said cold side of said thermoelectric chip, said first finned structure, and said cooling fan,
wherein said cooling fan is operable so as to draw air from said interior space in said computer housing into said cover through said inlet opening and so as to expel the air out of said cover through said outlet opening back to said interior space in said computer housing; and
a temperature control device coupled to said thermoelectric chip, and operable so as to control operation of said thermoelectric chip in order to maintain temperature of the air in said interior space in said computer housing above the dew point temperature.

2. The computer housing assembly as claimed in claim 1, wherein said cooling device further includes
a second cooling fan that is disposed externally of said computer housing proximate to said second finned structure, and
a second cover that is disposed externally of said computer housing, that is formed with outlet and inlet openings, and that encases said hot side of said thermoelectric chip, said second finned structure, and said second cooling fan,
said second cooling fan being operable so as to draw external air into said second cover through said inlet opening in said second cover and so as to expel the air out of said second cover through said outlet opening in said second cover.

3. The computer housing assembly as claimed in claim 1, wherein said outlet opening in said cover is disposed proximate to said cooling fan.

4. The computer housing assembly as claimed in claim 2, wherein said outlet opening in said second cover is disposed proximate to said second cooling fan.

5. The computer housing assembly as claimed in claim 1, wherein said temperature control device includes a sensor that is coupled to and that detects temperature of said first finned structure, and a current source that is coupled electrically to said thermoelectric chip.

6. The computer housing assembly as claimed in claim 3, wherein said first finned structure includes a heat sink body that is attached to said cold side of said thermoelectric chip, and an extension that extends from said heat sink body, that is provided with a plurality of fins, and that is disposed between said cooling fan and said outlet opening in said cover.

7. The computer housing assembly as claimed in claim 4, wherein said second finned structure includes a heat sink body that is attached to said hot side of said thermoelectric chip, and an extension that extends from said heat sink body, that is provided with a plurality of fins, and that is disposed between said second cooling fan and said outlet opening in said second cover.
